(19) United States
(12) Patent Application Publication
(10) Pub. No.: US 2025/0241155 A1
(43) Pub. Date: Jul. 24, 2025

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Yanwei LU, Beijing (CN); Yuanjie XU, Beijing (CN); Zhuoran YAN, Beijing (CN); Ni YANG, Beijing (CN); Lili DU, Beijing (CN); Benlian WANG, Beijing (CN); Weiyun HUANG, Beijing (CN); Qiwei WANG, Beijing (CN); Yudiao CHENG, Beijing (CN)

(21) Appl. No.: 18/685,512

(22) PCT Filed: Sep. 22, 2022
(86) PCT No.: PCT/CN2022/120574

§ 371 Date: Feb. 22, 2024

(30) Foreign Application Priority Data
May 13, 2022 (WO) PCT/CN2022/092606

(51) Int. Cl. H10K 59/131

(52) U.S. Cl. CPC H10K 59/1315

(57) ABSTRACT

A display substrate, comprising: a substrate, a plurality of first pixel circuits (11), a plurality of first light-emitting elements (21), and a plurality of connection lines (L). The plurality of connection lines (L) at least comprise: a plurality of first connection lines (31) located on a first connection layer. The plurality of first connection lines (31) comprise: at least one first-type first connection line (31a). The first-type first connection line (31a) comprises: successively connected, a first connection section (311), a second connection section (312), and a third connection section (313). The extension directions of the first connection section (311), the second connection section (312) and the third connection section (313) are different from each other.

### CROSS-REFERENCE TO RELATED APPLICATIONS

The present application is a U.S. National Phase Entry of International Application No. PCT/CN2022/120574 having an international filing date of Sep. 22, 2022, which claims priority to International Application No. PCT/CN2022/092606 having an international filing date of May 13, 2022 and entitled “Display Panel and Display Apparatus”, contents of the above-identified applications should be interpreted as being incorporated into the present application by reference.

### TECHNICAL FIELD

The present disclosure relates to, but is not limited to, the field of display technologies, in particular to a display substrate and a display apparatus.

### BACKGROUND

With constant development of display technologies, there are more and more kinds of display products, e.g., a Liquid Crystal Display (LCD), an Organic Light emitting Diode (OLED) display, a Plasma Display Panel (PDP), and a Field Emission Display (FED).

### SUMMARY

The following is a summary of subject matter described herein in detail. The summary is not intended to limit the scope of protection of claims.

Embodiments of the present disclosure provide a display substrate and a display apparatus.

In one aspect, an embodiment of the present disclosure provides a display substrate, which includes a base substrate, a plurality of first pixel circuits, a plurality of first light emitting elements, and a plurality of connection lines. The base substrate includes a first region and a second region located on at least one side of the first region. The plurality of first pixel circuits are located in the second region, and the plurality of first light emitting elements are located in the first region. At least one first pixel circuit among the plurality of first pixel circuits is electrically connected with at least one first light emitting element among the plurality of first light emitting elements through at least one connection line among the plurality of connection lines. The plurality of connection lines at least include a plurality of first connection lines located in a first connection layer, and the plurality of first connection lines include at least one first-type first connection line. The at least one first-type first connection line includes a first connection segment, a second connection segment, and a third connection segment connected in sequence. The first connection segment is electrically connected with the first light emitting element, and the third connection segment extends from the first region to the second region and is electrically connected with the first pixel circuit. Extension directions of the first connection segment, the second connection segment, and the third connection segment are different from each other.

In some exemplary implementation modes, the first connection segment and the second connection segment of the at least one first-type first connection line are connected and form a first corner along a clockwise direction, the second connection segment and the third connection segment are connected and form a second corner along a counter-clockwise direction, and the first corner is smaller than the second corner.

In some exemplary implementation modes, extension directions of the first connection segment and the second connection segment of the at least one first-type first connection line are substantially perpendicular; the plurality of first pixel circuits are arranged in an array, and an extension direction of at least part of the third connection segment is substantially parallel to a row direction of the plurality of first pixel circuits.

In some exemplary implementation modes, the plurality of first connection lines further include at least one second-type first connection line. The first connection segment and the second connection segment of the at least one first-type first connection line are located on a side of the at least one second-type first connection line close to a center of the first region.

In some exemplary implementation modes, the at least one second-type first connection line includes a fourth connection segment and a fifth connection segment connected in sequence, wherein the fourth connection segment is electrically connected with at least one first light emitting element and extends from the first region to the second region, and the fifth connection segment is electrically connected with a first pixel circuit in the second region; an extension direction of the fourth connection segment is different from an extension direction of the fifth connection segment, and the extension direction of the fifth connection segment is approximately the same as an extension direction of the third connection segment of the first-type first connection line.

In some exemplary implementation modes, the plurality of connection lines further include a plurality of second connection lines located in a second connection layer, and the second connection layer is located on a side of the first connection layer away from the base substrate. A first light emitting element electrically connected with at least one second connection line among the plurality of second connection lines is located between a first light emitting element electrically connected with the at least one first-type first connection line and a first light emitting element electrically connected with the at least one second-type first connection line.

In some exemplary implementation modes, the plurality of second connection lines include at least one first-type second connection line and at least one second-type second connection line. The at least one first-type second connection line includes a sixth connection segment, a seventh connection segment, and an eighth connection segment connected in sequence, wherein the sixth connection segment is connected electrically with the at least one first light emitting element, the eighth connection segment extends from the first region to the second region and is electrically connected with a first pixel circuit in the second region; extension directions of the sixth connection segment, the seventh connection segment, and the eighth connection segment are different from each other. The sixth connection segment and the seventh connection segment of the at least one first-type second connection line are located on a side of the at least one second-type second connection line close to the center of the first region.

In some exemplary implementation modes, an extension direction of the sixth connection segment of the at least one first-type second connection line is substantially the same as an extension direction of the first connection segment of the at least one first-type first connection line, an extension direction of the seventh connection segment of the at least one first-type second connection line is substantially the same as an extension direction of the second connection segment of the at least one first-type first connection line, and an extension direction of the eighth connection segment of the at least one first-type second connection line is substantially the same as an extension direction of the third connection segment of the at least one first-type first connection line.

In some exemplary implementation modes, the plurality of connection lines further include a plurality of third connection lines located in a third connection layer, and the third connection layer is located on a side of the second connection layer away from the base substrate. A first light emitting element electrically connected with at least one third connection line among the plurality of third connection lines is located between a first light emitting element electrically connected with the at least one first-type second connection line and a first light emitting element electrically connected with the at least one second-type second connection line.

In some exemplary implementation modes, in a direction from the center to an edge of the first region, a plurality of first light emitting elements arranged along an extension direction of the first connection segment are electrically connected with at least one first-type first connection line, at least one first-type second connection line, at least one third connection line, at least one second-type second connection line, and at least one second-type first connection line in sequence.

In some exemplary implementation modes, the first region has a plurality of sub-pixel regions arranged in an array, each sub-pixel region is provided with a switching hole, and an anode of the first light emitting element is electrically connected with a corresponding connection line through the switching hole.

In some exemplary implementation modes, in a row of sub-pixel regions, switching holes within adjacent sub-pixel regions are misaligned in a row direction.

In some exemplary implementation modes, a column of sub-pixel regions includes a plurality of first sub-pixel region units arranged in sequence, each first sub-pixel region unit includes two adjacent sub-pixel regions, and two switching holes within each first sub-pixel region unit are close to a junction position of the two sub-pixel regions.

In some exemplary implementation modes, four sub-pixel regions arranged in a 2×2 array are used as one second sub-pixel region unit, and four switching holes within each second sub-pixel region unit are centrally arranged with a center of the second sub-pixel region unit as a center.

In some exemplary implementation modes, a plurality of switching holes arranged along an extension direction of the first connection segment are taken as a group of switching holes, and a plurality of first-type first connection lines electrically connected with the first light emitting element through the group of switching holes are located on one side of the group of switching holes.

In some exemplary implementation modes, a plurality of switching holes arranged along an extension direction of the first connection segment are taken as a group of switching holes, and a plurality of first-type first connection lines electrically connected with the first light emitting element through the group of switching holes are located on two opposite sides of the group of switching holes.

In some exemplary implementation modes, a material of the plurality of connection lines includes a transparent conductive material.

In some exemplary implementation modes, the display substrate further includes a plurality of second pixel circuits and a plurality of second light emitting elements located in the second region, wherein at least one second pixel circuit among the plurality of second pixel circuits is electrically connected with at least one second light emitting element among the plurality of second light emitting elements.

In another aspect, an embodiment of the present disclosure provides a display apparatus, which includes the aforementioned display substrate.

After drawings and detailed description are read and understood, other aspects may be comprehended.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a display substrate according to at least one embodiment of the present disclosure.

FIG. 2 is a schematic diagram of a connection line of a first display region according to at least one embodiment of the present disclosure.

FIGS. 3A to 3C are partial trace diagrams of a first connection layer of a first display region according to at least one embodiment of the present disclosure.

FIG. 3D is a partial schematic diagram of a first connection line and a switching hole according to at least one embodiment of the present disclosure.

FIGS. 4A and 4B are partial trace diagrams of a second connection layer of a first display region according to at least one embodiment of the present disclosure.

FIGS. 5A and 5B are partial trace diagrams of a third connection layer of a first display region according to at least one embodiment of the present disclosure.

FIG. 6 is a schematic diagram of a resistance change of a connection line with which a row of first light emitting elements of a first display region within a display substrate are electrically connected.

FIGS. 7A to 7D are another partial schematic diagram of a first connection line and a switching hole according to at least one embodiment of the present disclosure.

FIG. 8 is another schematic diagram of a connection line of a display substrate according to at least one embodiment of the present disclosure.

FIG. 9 is another schematic diagram of a connection line in a first display region according to at least one embodiment of the present disclosure.

FIG. 10A is a partial schematic diagram of a first connection line and a switching hole of a first display region according to at least one embodiment of the present disclosure.

FIG. 10B is a partial schematic diagram of a first connection line of a first display region according to at least one embodiment of the present disclosure.

FIG. 10C is a partial schematic diagram of a first connection line and a switching hole according to at least one embodiment of the present disclosure.

FIG. 10D is a partial schematic diagram of a second connection line of a first display region according to at least one embodiment of the present disclosure.

FIG. 11 is a schematic diagram of a display apparatus according to at least one embodiment of the present disclosure.

### DETAILED DESCRIPTION

The embodiments of the present disclosure will be described below with reference to the drawings in detail. Implementation modes may be implemented in multiple different forms. Those of ordinary skills in the art may easily understand such a fact that modes and contents may be transformed into other forms without departing from the purpose and scope of the present disclosure. Therefore, the present disclosure should not be explained as being limited to contents recorded in following implementation modes only. The embodiments in the present disclosure and features in the embodiments may be randomly combined with each other in case of no conflict.

In the drawings, for the sake of clarity, a size of one or more constituent elements, a thickness of a layer, or a region is sometimes exaggerated. Therefore, one mode of the present disclosure is not necessarily limited to the size, and a shape and a size of one or more components in the drawings do not reflect an actual scale. In addition, the accompanying drawings schematically illustrate ideal examples, and one mode of the present disclosure is not limited to shapes, numerical values, or the like shown in the drawings.

Ordinal numerals “first”, “second”, “third”, etc., in the specification are set to avoid confusion of constituent elements, not to limit a quantity. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating orientations or positional relationships are used for illustrating positional relationships between constituent elements with reference to the drawings, only to facilitate description of the specification and simplify the description, not to indicate or imply that a referred apparatus or element must have a specific orientation and be structured and operated with the specific orientation, and thus should not be understood as limitations on the present disclosure. The positional relationships between the constituent elements are changed as appropriate according to a direction where the constituent elements are described. Therefore, appropriate replacements may be made according to situations, not limited to the expressions in the specification.

In the specification, unless otherwise specified and defined, terms “mounting”, “mutual connection”, and “connection” should be generally understood. For example, it may be a fixed connection, a detachable connection, or an integrated connection; it may be a mechanical connection or a connection; it may be a direct connection, an indirect connection through a middleware, or internal communication inside two elements. Those of ordinary skills in the art may understand meanings of the above-mentioned terms in the present disclosure according to situations.

In the specification, an “electrical connection” includes a case that constituent elements are connected together through an element having some electrical function. The “element having some electrical function” is not particularly limited as long as electrical signals between the connected constituent elements may be transmitted. Examples of the “element having some electrical function” not only include an electrode and a wiring, but also include a switching element such as a transistor, a resistor, an inductor, a capacitor, another element with a plurality of functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, to distinguish two electrodes of a transistor except a gate, one of the electrodes is referred to as a first electrode and the other electrode is referred to as a second electrode. The first electrode may be a source or a drain, and the second electrode may be a drain or a source. In addition, the gate of the transistor is referred to as a control electrode. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification.

In the specification, “parallel” refers to a state in which an angle formed by two straight lines is more than −10° and less than 10°, including, for example, a state in which the angle is more than −5° and less than 5°. In addition, “perpendicular” refers to a state in which an angle formed by two straight lines is more than 70° and less than 120°, including, for example, a state in which the angle is more than 80° and less than 110°.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, and deformation, etc.

A “light transmission rate” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. In following description, “A extends along a B direction” means “a main body portion of A extends along the B direction”.

An embodiment of the present disclosure provides a display substrate, which includes a base substrate, a plurality of first pixel circuits, a plurality of first light emitting elements, and a plurality of connection lines. The base substrate includes a first region and a second region located on at least one side of the first region. The plurality of first pixel circuits are located in the second region, and the plurality of first light emitting elements are located in the first region. At least one first pixel circuit among the plurality of first pixel circuits is electrically connected with at least one first light emitting element among the plurality of first light emitting elements through at least one connection line among the plurality of connection lines. The plurality of connection lines at least include a plurality of first connection lines located in a first connection layer, and the plurality of first connection lines include at least one first-type first connection line. The at least one first-type first connection line includes a first connection segment, a second connection segment, and a third connection segment connected in sequence. The first connection segment is electrically connected with the first light emitting element, and the third connection segment extends from the first region to the second region and is electrically connected with the first pixel circuit. Extension directions of the first connection segment, the second connection segment, and the third connection segment are different from each other.

In some examples, both of the first region and the second region may be located in a display region, and the first pixel circuits are arranged by compressing pixel circuits in the second region. Or, the first region is located in the display region and the second region may be located in a peripheral region at a periphery of the display region. However, this embodiment is not limited thereto.

In the display substrate provided by the embodiment, first-type first connection lines are arranged, and the first-type first connection line has a plurality of connection segments with different extension directions, so that trace space of the first region may be utilized to a great extent, more connection lines may be arranged in limited space, which is beneficial to increasing a size of the first region. Moreover, a trace arrangement mode of the embodiment is helpful to improve an abrupt change of resistance of connection lines with different extension directions at a junction, and is beneficial to improve a situation of striped display Mura of the display panel.

In some exemplary implementation modes, the plurality of first connection lines may further include at least one second-type first connection line. The first connection segment and the second connection segment of the at least one first-type first connection line are located on a side of the at least one second-type first connection line close to a center of the first region. In the example, the second-type first connection line is disposed on a side of the first connection segment and the second connection segment of the first-type first connection line away from the center of the first region, which facilitates increasing a size of the first region.

In some exemplary implementation modes, the first connection segment and the second connection segment of the at least one first-type first connection line may be connected and form a first corner along a clockwise direction, the second connection segment and the third connection segment may be connected and form a second corner along a counter-clockwise direction. Among them, the first corner may be smaller than the second corner. In the example, by setting that the first-type first connection line extends to the second region after forming two corners in the first region, a combination mode of a turning trace and a transverse trace may be formed, thereby trace space of the first region is utilized to a great extent and a size of the first region can be increased.

In some exemplary implementation modes, the at least one second-type first connection line may include a fourth connection segment and a fifth connection segment connected in sequence. The fourth connection segment is electrically connected with the at least one first light emitting element and extends from the first region to the second region, and the fifth connection segment is electrically connected with a first pixel circuit in the second region. An extension direction of the fourth connection segment is different from an extension direction of the fifth connection segment, and the extension direction of the fifth connection segment is substantially the same as an extension direction of the third connection segment of the first-type first connection line. In the example, a combination mode of oblique and transverse traces may be adopted for the second-type first connection line, which is beneficial to increase a size of the first region.

In some exemplary implementation modes, the plurality of connection lines may further include a plurality of second connection lines located in a second connection layer, the second connection layer may be located on a side of the first connection layer away from the base substrate. A first light emitting element electrically connected with at least one second connection line among the plurality of second connection lines may be located between a first light emitting element electrically connected with at least one first-type first connection line and a first light emitting element electrically connected with at least one second-type first connection line. In some examples, the display substrate may include two connection layers to achieve an electrical connection between a first pixel circuit and a first light emitting element, and more connection lines may be arranged within limited space, which is beneficial to increase a size of the first region.

In some exemplary implementation modes, the plurality of second connection lines may include at least one first-type second connection line and at least one second-type second connection line. The at least one first-type second connection line may include a sixth connection segment, a seventh connection segment, and an eighth connection segment connected in sequence, wherein the sixth connection segment is connected electrically with the at least one first light emitting element, the eighth connection segment extends from the first region to the second region and is electrically connected with a first pixel circuit of the second region. Extension directions of the sixth connection segment, the seventh connection segment, and the eighth connection segment are different from each other. The sixth connection segment and the seventh connection segment of the at least one first-type second connection line may be located on a side of the at least one second-type second connection line close to the center of the first region. In the example, for a trace arrangement mode of the first-type second connection line of the second connection layer, a combination mode of a turning trace and a transverse trace may also be adopted, so as to improve a trace space utilization rate of the first region and increase a size of the first region.

In some exemplary implementation modes, the plurality of connection lines may further include a plurality of third connection lines located in a third connection layer, the third connection layer may be located on a side of the second connection layer away from the base substrate. A first light emitting element electrically connected with at least one third connection line among the plurality of third connection lines may be located between a first light emitting element electrically connected with at least one first-type second connection line and a first light emitting element electrically connected with at least one second-type second connection line. In some examples, the display substrate may include three connection layers to achieve an electrical connection between a first pixel circuit and a first light emitting element, and more connection lines may be arranged within limited space, which is beneficial to increase a size of the first region.

In some exemplary embodiments, the first region has a plurality of sub-pixel regions arranged in an array, and each sub-pixel region is provided with a switching hole. An anode of a first light emitting element is electrically connected with a corresponding connection line through a switching hole. In some examples, in a row of sub-pixel regions, switching holes within adjacent sub-pixel regions may be misaligned in a row direction. In other examples, in a row of sub-pixel regions, switching holes within adjacent sub-pixel regions may be misaligned in a row direction, a column of sub-pixel regions may include a plurality of first sub-pixel region units arranged in sequence, each first sub-pixel region unit includes two adjacent sub-pixel regions, and two switching holes within each first sub-pixel region unit may be close to a junction position of the two sub-pixel regions. In other examples, four sub-pixel regions arranged in a 2×2 array may be used as one second sub-pixel region unit, and four switching holes within each second sub-pixel region unit are centrally arranged with a center of the second sub-pixel region unit as a center. In the example, by adjusting arrangement of switching holes, trace space may be provided for connection lines extending in different directions, which is beneficial to improve a trace space utilization rate of the first region, so as to increase a size of the first region.

In some exemplary implementation modes, a plurality of switching holes arranged along an extension direction of the first connection segment serve as a group of switching holes, and a plurality of first-type first connection lines electrically connected with a first light emitting element through the group of switching holes may be located on a side of the group of switching holes; or may be located on opposite sides of the group of switching holes. In the example, by arranging first-type first connection lines on one side or opposite sides of the group of switching holes, it is beneficial to make full use of trace space, reduce a quantity of connection layers, and improve a situation of striped display Mura caused by uneven lengths of connection lines.

Solutions of the embodiments will be described below through some examples.

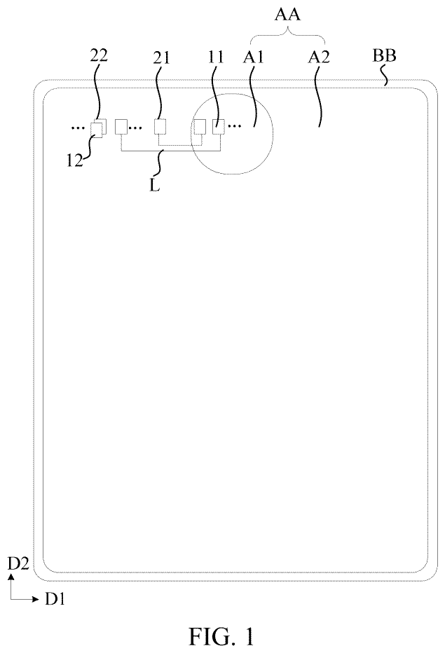

FIG. 1 is a schematic diagram of a display substrate according to at least one embodiment of the present disclosure. In some examples, as shown in FIG. 1, the display substrate may include a display region AA and a peripheral region BB surrounding a periphery of the display region AA. The display region AA of the display substrate may include a first display region A1 and a second display region A2. The second display region A2 may at least partially surround the first display region A1. In the example, the second display region A2 may surround the first display region A1. In the example, the first region may be the first display region A1, and the second region may be the second display region A2. In other examples, the second region may be the peripheral region BB.

In some examples, as shown in FIG. 1, the first display region A1 may be a light-transmitting display region, and may also be referred to as a Full Display with Camera (FDC) region, and the second display region A2 may be a normal display region. For example, an orthographic projection of a photosensitive sensor (such as a camera and other hardware) on the display substrate may be located within the first display region A1 of the display substrate. In some examples, as shown in FIG. 1, the first display region A1 may be circular and a dimension of the orthographic projection of the photosensitive sensor on the display substrate may be less than or equal to a dimension of the first display region A1. However, the embodiment is not limited thereto. In other examples, the first display region A1 may be rectangular, and a dimension of the orthographic projection of the photosensitive sensor on the display substrate may be less than or equal to a dimension of an inscribed circle of the first display region A1.

In some examples, as shown in FIG. 1, the first display region A1 may be located at a middle position of a top of the display region AA. The second display region A2 may surround the first display region A1. However, the embodiment is not limited thereto. For example, the first display region A1 may be located at another position such as an upper left corner or an upper right corner of the display region AA. For example, the second display region A2 may surround at least one side of the first display region A1.

In some examples, as shown in FIG. 1, the display region AA may be in a shape of a rectangle, e.g., a rounded rectangle. The first display region A1 may be circular or elliptical. However, the embodiment is not limited thereto. For example, the first display region A1 may be rectangular, semicircular, pentagonal, or have another shape.

In some examples, the display region AA may be provided with a plurality of sub-pixels. At least one sub-pixel may include a pixel circuit and a light emitting element. The pixel circuit may be configured to drive a connected light emitting element. For example, the pixel circuit is configured to provide a drive current to drive the light emitting element to emit light. The pixel circuit may include a plurality of transistors and at least one capacitor. For example, the pixel circuit may be of a 3T1C, 4T1C, 5T1C, 5T2C, 6T1C, 7T1C, or 8T1C structure. Among them, in the above circuit structure, T refers to a thin film transistor, C refers to a capacitor, a number before T represents a quantity of thin film transistors in the circuit, and a number before C represents a quantity of capacitors in the circuit.

In some examples, the plurality of transistors in the pixel circuit may be P-type transistors or may be N-type transistors. Use of a same type of transistors in the pixel circuit may simplify a process flow, reduce a process difficulty of the display substrate, and improve a yield of products. In other examples, the plurality of transistors in the pixel circuit may include a P-type transistor and an N-type transistor.

In some examples, low temperature poly silicon thin film transistors, or oxide thin film transistors, or a low temperature poly silicon thin film transistor and an oxide thin film transistor may be adopted for the plurality of transistors in the pixel circuit. An active layer of the low temperature poly silicon thin film transistor is made of Low Temperature Poly Silicon (LTPS), and an active layer of an oxide thin film transistor is made of an oxide semiconductor (Oxide). The low temperature poly silicon thin film transistor has advantages such as a high migration rate and fast charging, and the oxide thin film transistor has advantages such as a low leakage current. The low temperature poly silicon thin film transistor and the oxide thin film transistor are integrated on one display panel, that is, an LTPS+Oxide (LTPO for short) display panel, advantages of both the low temperature poly silicon thin film transistor and the oxide thin film transistor may be utilized, so that low-frequency drive may be achieved, power consumption may be reduced, and display quality may be improved.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected with a corresponding pixel circuit. However, the embodiment is not limited thereto.

In some examples, one pixel unit of the display region AA may include three sub-pixels, and the three sub-pixels may be a red sub-pixel, a green sub-pixel, and a blue sub-pixel, respectively. However, the embodiment is not limited thereto. In some examples, one pixel unit may include four sub-pixels, and the four sub-pixels may be a red sub-pixel, a green sub-pixel, a blue sub-pixel, and a white sub-pixel, respectively.

In some examples, a shape of the light emitting element may be a rectangle, a rhombus, a pentagon, or a hexagon. When one pixel unit includes three sub-pixels, light emitting elements of the three sub-pixels may be arranged in a manner to stand side by side horizontally, in a manner to stand side by side vertically, or in a manner like a Chinese character “H”. When one pixel unit includes four sub-pixels, light emitting elements of the four sub-pixels may be arranged in a manner to stand side by side horizontally, in a manner to stand side by side vertically, or in a manner to form a square. However, the embodiment is not limited thereto.

In some examples, as shown in FIG. 1, the first display region A1 may include a plurality of first light emitting elements 11 arranged in an array. The second display region A2 may include a plurality of first pixel circuits 21 and a plurality of second pixel circuits 22 arranged in an array, and may further include a plurality of second light emitting elements 12. In some examples, a first direction D1 may be parallel to a row direction of the plurality of first light emitting elements 11 and the plurality of second light emitting elements 12, and may also be parallel to a row direction of the plurality of first pixel circuits 21 and the plurality of second pixel circuits 22. A second direction D2 may be parallel to a column direction of the plurality of first light emitting elements 11 and the plurality of second light emitting elements 12, and may also be parallel to a column direction of the plurality of first pixel circuits 21 and the plurality of second pixel circuits 22.

In some examples, as shown in FIG. 1, at least one first pixel circuit 21 within the second display region A2 may be electrically connected with at least one first light emitting element 11 within the first display region A1 through a connection line L, and configured to drive the at least one first light emitting element 11 to emit light. For example, one first pixel circuit 21 may be configured to drive one first light emitting element 11 to emit light, or may be configured to drive at least two first light emitting elements 11 (e.g., at least two first light emitting elements 11 emitting light of a same color) to emit light. An orthographic projection of a first light emitting element 11 on the base substrate may be not overlapped with an orthographic projection of an electrically connected first pixel circuit 21 on the base substrate. At least one second pixel circuit 22 within the second display region A2 may be electrically connected with at least one second light emitting element 12, and configured to drive the at least one second light emitting element 12 to emit light. For example, one second pixel circuit 22 may be configured to drive one second light emitting element 12 to emit light, or may be configured to drive at least two second light emitting elements 12 (e.g., at least two second light emitting elements 12 emitting light of a same color) to emit light. An orthographic projection of a second pixel circuit 22 may be at least partially overlapped with an orthographic projection of an electrically connected second light emitting element 12 on the base substrate. In the example, by disposing a first pixel circuit 21 for driving a first light emitting device in the second display region A2, sheltering of light by a pixel circuit may be reduced, thereby increasing a light transmittance of the first display region A1.

In some examples, the second display region A2 may also be provided with a plurality of invalid pixel circuits. It may be beneficial to improve uniformity of components of a plurality of film layers in an etching process by disposing an invalid pixel circuit. For example, a structure of the invalid pixel circuit may be substantially the same as structures of a first pixel circuit 21 and a second pixel circuit 22 of a row or column in which the invalid pixel circuit is located, except that it is not electrically connected with any light emitting element.

In some examples, since the second display region A2 is not only provided with a second pixel circuit 22 electrically connected with a second light emitting element 12, but also provided with a first pixel circuit 21 electrically connected with a first light emitting element 11, a quantity of pixel circuits of the second display region A2 may be greater than a quantity of second light emitting elements. In some examples, a region where newly added pixel circuits (including a first pixel circuit and an invalid pixel circuit) are disposed may be obtained by reducing a dimension of a second pixel circuit in the first direction D1. For example, a dimension of a pixel circuit in the first direction D1 may be smaller than a dimension of a second light emitting element in the first direction D1. For example, original a columns of pixel circuits may be compressed along the first direction D1, so that arrangement space of one column of pixel circuits may be added, and space occupied by a columns of pixel circuits before compression and space occupied by a+1 columns of pixel circuits after compression may be the same, wherein a may be an integer greater than 1. In some examples, a may be equal to 4. However, the embodiment is not limited thereto. For example, a may be equal to 2 or 3.

In other examples, original b rows of pixel circuits may be compressed along the second direction D2, so that arrangement space of one row of pixel circuits is added, and space occupied by b rows of pixel circuits before compression and space occupied by b+1 rows of pixel circuits after compression are the same, wherein b may be an integer greater than 1. Or, a region in which a newly added pixel circuit is disposed may be obtained by reducing a dimension of a second pixel circuit in the first direction D1 and the second direction D2.

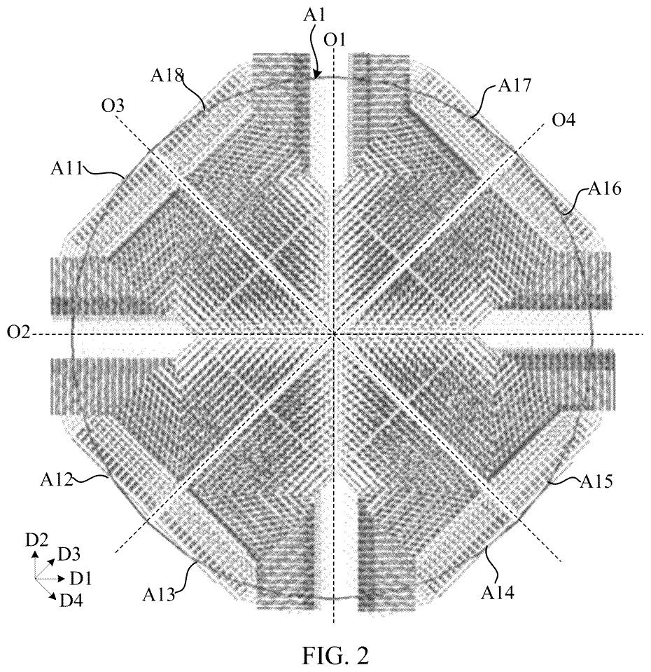

FIG. 2 is a schematic diagram of a connection line of a first display region according to at least one embodiment of the present disclosure. In some examples, as shown in FIG. 2, the first display region A1 may be substantially circular or elliptical. The first display region A1 may have a first centerline O1 in the first direction D1 (e.g., the first centerline O1 may be parallel to the second direction D2), a second centerline O2 in the second direction D2 (e.g., the second centerline O2 may be parallel to the first direction D1), a third centerline O3 in a third direction D3 (e.g., the third centerline O3 may be parallel to a fourth direction D4), and a fourth centerline O4 in the fourth direction D4 (e.g., the fourth centerline O4 may be parallel to the third direction D3). Among them, the first centerline O1, the second centerline O2, the third centerline O3, and the fourth centerline O4 all pass through a center point of the first display region A1.

In some examples, as shown in FIG. 2, the first direction D1 and the second direction D2 may be perpendicular to each other, and the third direction D3 and the fourth direction D3 may be perpendicular to each other. The first centerline O1 and the second centerline O2 may be perpendicular to each other, and the third centerline O3 and the fourth centerline O4 may be perpendicular to each other. The third direction D3 may intersect with the first direction D1 and the second direction D2, and the fourth direction D4 may intersect with the first direction D1 and the second direction D2. For example, a sum of a counter-clockwise included angle between the first direction D1 and the third direction D3 and a clockwise included angle between the first direction D1 and the fourth direction D4 may be 90 degrees. For example, the counter-clockwise included angle between the first direction D1 and the third direction D3 may be about 30 degrees to 60 degrees, e.g., may be about 45 degrees, and the clockwise included angle between the first direction D1 and the fourth direction D4 may be about 30 degrees to 60 degrees, e.g., may be about 45 degrees. For example, an included angle between the first centerline O1 and the third centerline O3 may be about 45 degrees, an included angle between the first centerline O1 and the fourth centerline O4 may be about 45 degrees, an included angle between the second centerline O2 and the third centerline O3 may be about 45 degrees, and an included angle between the second centerline O2 and the fourth centerline O4 may be about 45 degrees. However, the embodiment is not limited thereto.

In some examples, as shown in FIG. 2, the first centerline O1, the second centerline O2, the third centerline O3, and the fourth centerline O3 may divide the first display region A1 into eight sub-regions, such as a first sub-region A11, a second sub-region A12, a third sub-region A13, a fourth sub-region A14, a fifth sub-region A15, a sixth sub-region A16, a seventh sub-region A17, and an eighth sub-region A18. In some examples, sizes and shapes of the first sub-region A11 to the eighth sub-region A18 may be substantially the same. However, the embodiment is not limited thereto.

In some examples, as shown in FIG. 2, a connection line within the first sub-region A11 and a connection line within the second sub-region A12 may be approximately symmetrical with respect to the second centerline O2, a connection line within the third sub-region A13 and a connection line within the fourth sub-region A14 may be approximately symmetrical with respect to the first centerline O1, connection lines within the fifth sub-region A15 and the sixth sub-region A16 may be approximately symmetrical with respect to the second centerline O2, and connection lines within the seventh sub-region A17 and the eighth sub-region A18 may be approximately symmetrical with respect to the first centerline O1. A connection line within the first sub-region A11 and a connection line within the eighth sub-region A18 may be substantially symmetrical with respect to the third centerline O3, connection lines within the second sub-region A12 and the third sub-region A13 may be substantially symmetrical with respect to the fourth centerline O4, connection lines within the fourth sub-region A14 and the fifth sub-region A15 may be substantially symmetrical with respect to the third centerline O3, and connection lines within the sixth sub-region A16 and the seventh sub-region A17 may be substantially symmetrical with respect to the fourth centerline O4.

The connection line in the first sub-region A11 is taken as an example for description below. Connection lines within the second sub-region A12 to the eighth sub-region A18 may be obtained by referring to a connection line within the first sub-region A11, which will not be repeated here. In some examples, a first light emitting element close to a center of a first display region may be electrically connected with a first pixel circuit within a second display region away from the first display region, and a first light emitting element close to an edge of the first display region may be electrically connected with a first pixel circuit within the second display region close to the first display region. However, the embodiment is not limited thereto.

In some examples, in a direction perpendicular to the display substrate, the display substrate may include a base substrate, and a circuit structure layer, a first connection layer, a second connection layer, a third connection layer, and a light emitting structure layer sequentially disposed on the base substrate. The circuit structure layer of the second display region may include a plurality of first pixel circuits, a plurality of second pixel circuits, and a plurality of invalid pixel circuits.

For example, the circuit structure layer of the second display region may include a semiconductor layer, a first insulation layer, a first gate metal layer, a second insulation layer, a second gate metal layer, a third insulation layer, a first source-drain metal layer, a fourth insulation layer, a second source-drain metal layer, and a fifth insulation layer that are sequentially disposed on the base substrate. The circuit structure layer of the first display region may include a plurality of insulation layers (e.g., a first insulation layer to a fifth insulation layer) that are stacked. In some examples, the first gate metal layer, the second gate metal layer, the first source-drain metal layer, and the second source-drain metal layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, and the fourth insulation layer may be made of any one or more of Silicon Oxide (SiOx), Silicon Nitride (SiNx), and Silicon Oxynitride (SiON), and may be a single layer, a multi-layer, or a composite layer. The fifth insulation layer may be made of an organic material, such as polyimide, acrylic, or polyethylene terephthalate. However, the embodiment is not limited thereto.

In some examples, a first planarization layer may be disposed between the first connection layer and the second connection layer, a second planarization layer may be disposed between the second connection layer and the third connection layer, and a third planarization layer may be disposed between the third connection layer and the light emitting structure layer. The first connection layer to the third connection layer may be made of a transparent conductive material, such as Indium Tin Oxide (ITO). The first connection layer may include, at least, a plurality of first connection lines, the second connection layer may include, at least, a plurality of second connection lines, and the third connection layer may include, at least, a plurality of third connection lines. For example, the first planarization layer to the third planarization layer may be made of an organic material, such as polyimide, acrylic, or polyethylene terephthalate.

In some examples, the light emitting structure layer may include an anode layer (e.g., including an anode of a first light emitting element located in the first display region, and an anode of a second light emitting element located in the second display region), a pixel definition layer, an organic emitting layer, and a cathode layer. The pixel definition layer may be made of an organic material, such as polyimide, acrylic, or polyethylene terephthalate. For example, the anode layer may be made of a reflective material such as a metal, and the cathode layer may be made of a transparent conductive material. However, the embodiment is not limited thereto.

In some examples, the anode of the first light emitting element may be electrically connected with a corresponding connection line through a switching hole opened in a planarization layer. For example, a switching hole corresponding to the anode of the first light emitting element may include a third switching hole opened in the third planarization layer. Among them, the anode of the first light emitting element may be electrically connected with one third connection line located in the third connection layer through the third switching hole opened in the third planarization layer, and electrically connected with a first pixel circuit of the second display region through the third connection line. For another example, the switching hole corresponding to the anode of the first light emitting element may include a third switching hole opened in the third planarization layer and a second switching hole opened in the second planarization layer. Among them, the anode of the first light emitting element may be electrically connected with a third connection electrode located in the third connection layer through the third switching hole opened in the third planarization layer, the third connection electrode may be electrically connected with a second connection line located in the second connection layer through the second switching hole opened in the second planarization layer, and may be electrically connected with a first pixel circuit of the second display region through the second connection line. For another example, the switching hole corresponding to the anode of the first light emitting element may include a third switching hole opened in the third planarization layer, a second switching hole opened in the second planarization layer, and a first switching hole opened in the first planarization layer. Among them, the anode of the first light emitting element may be electrically connected with a third connection electrode located in the third connection layer through the third switching hole opened in the third planarization layer, the third connection electrode may be electrically connected with a second connection electrode located in the second connection layer through the second switching hole opened in the second planarization layer, the second connection electrode may be electrically connected with a first connection electrode located in the first connection layer through the first switching hole opened in the first planarization layer, the first connection electrode and the first connection line may be of an integral structure, and the first connection electrode is electrically connected with the first pixel circuit of the second display region through the first connection line. However, the embodiment is not limited thereto. For example, the third planarization layer within a switching hole corresponding to the anode of the first light emitting element may be removed to expose a corresponding third connection line. Or, the third planarization layer and the second planarization layer within a switching hole corresponding to the anode of the first light emitting element may be removed to expose a corresponding second connection line. Or, the third planarization layer, the second planarization layer, and the first planarization layer within a switching hole corresponding to the anode of the first light emitting element may be removed to expose a corresponding first connection line.

In the example, no matter whether a quantity of connection holes corresponding to the anode of the first light emitting element is one or more, positions of switching holes corresponding to an anode of a same first light emitting element are substantially the same. A position of the switching hole corresponding to the anode of the first light emitting element is indicated by a black square in following drawings.

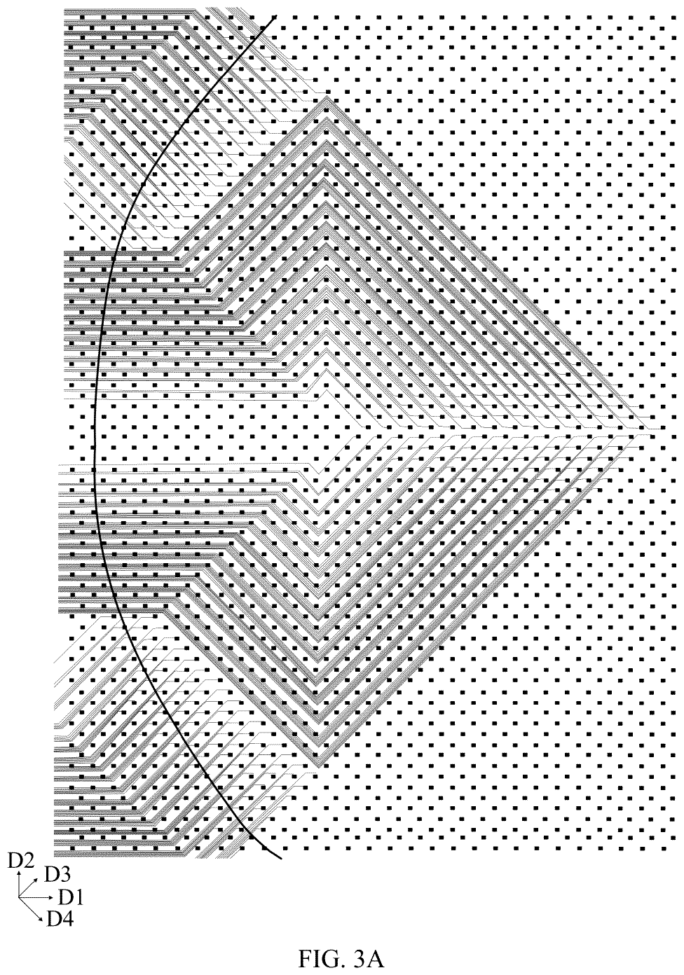

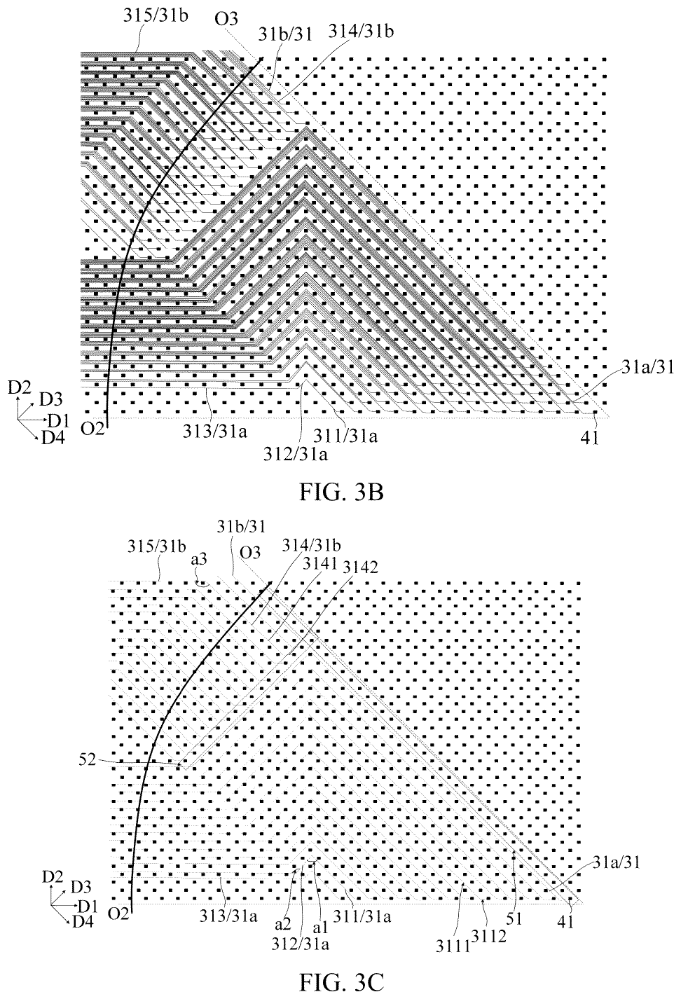

FIGS. 3A to 3C are partial trace diagrams of a first connection layer of a first display region according to at least one embodiment of the present disclosure. FIG. 3A is a schematic diagram of a first connection line within a first sub-region and a second sub-region, and FIG. 3B is a schematic diagram of a first connection line within the first sub-region. The first sub-region is a region between the second centerline O2 and the third centerline O3 within the first display region. FIG. 3C is a schematic diagram of a portion of the first connection line within the first sub-region.

In some examples, as shown in FIGS. 3A and 3B, a plurality of first connection lines 31 of the first connection layer may include a plurality of first-type first connection lines 31a and a plurality of second-type first connection lines 31b. A first light emitting element electrically connected with the plurality of first-type first connection lines 31a may be located on a side of a first light emitting elements electrically connected with the plurality of second-type first connection lines 31b close to a center of the first display region.

In some examples, as shown in FIGS. 3A to 3C, a first-type first connection line 31a of the first sub-region may include a first connection segment 311, a second connection segment 312, and a third connection segment 313 connected in sequence. The first connection segment 311 may at least extend along a fourth direction D4. For example, the first connection segment 311 may include a first main body 3111 extending along the fourth direction D4 and a first extension portion 3112 extending along a first direction D1, and the first extension portion 3112 of the first connection segment 311 may be electrically connected with an anode of a first light emitting element. The second connection segment 312 may extend along a third direction D3. The third connection segment 313 may extend from the first display region to a second display region along the first direction D1. The first connection segment 311 and the second connection segment 312 may be located in the first display region. The first connection segment 311 and the second connection segment 312 of the first-type first connection line 31a may be located on a side of a second-type first connection line 31b close to the center of the first display region. First connection segments 311 of a plurality of first-type first connection lines 31a may be arranged in sequence along the third direction D3, and a plurality of first connection segments 311 may be divided into a plurality of groups in a direction from the second centerline O2 to the third centerline O3 along the third direction D3, and lengths of the plurality of groups of first connection segments 311 may be increased gradually. Second connection segments 312 of the plurality of first-type first connection lines 31a may be arranged in sequence along the fourth direction D4, and a plurality of second connection segments 312 may be divided into a plurality of groups in a direction from a center to an edge of the first sub-region along the fourth direction D4, and lengths of a plurality of groups of second connection segments 312 may be increased gradually. For example, a length of a first connection segment 311 and a second connection segment 312 of a group of first-type connection lines 31a closest to the third centerline O3 within the first sub-region may be greater than a length of a first connection segment 311 and a second connection segment 312 of a group of first-type first connection lines 31a far away from the third centerline O3. In some examples, a length of a first connection segment 311 of one first-type first connection line 31a may be greater than a length of a second connection segment 312.

In some examples, as shown in FIGS. 3A to 3C, a first connection segment 311 and a second connection segment 312 of a first-type first connection line 31a may be connected and form a first corner a1 along a clockwise direction, and a second connection segment 312 and a third connection segment 313 may be connected and form a second corner a2 along a counter-clockwise direction. The first corner a1 may be a clockwise included angle between the first connection segment 311 and the second connection segment 312 and the second corner a2 may be a counter-clockwise included angle between the second connection segment 312 and the third connection segment 313. Among them, the first corner a1 and the second corner a2 may both be less than 180 degrees. The first corner a1 may be smaller than the second corner a2. For example, the first corner a1 may be about 90 degrees and the second corner a2 may be about 135 degrees. However, the embodiment is not limited thereto.

In some examples, as shown in FIGS. 3A to 3C, a second-type first connection line 31b of the first sub-region may include a fourth connection segment 314 and a fifth connection segment 315 connected in sequence. The fourth connection segment 314 may be electrically connected with a first light emitting element in the first display region and extend to the second display region along the fourth direction D4. For example, the fourth connection segment 314 may include a second main body 3141 extending along the fourth direction D4 and a second extension portion 3142 extending along the first direction D1, and the second extension portion 3142 of the fourth connection segment 314 may be electrically connected with an anode of the first light emitting element. The fifth connection segment 315 may at least extend along the first direction D1 and is electrically connected with a first pixel circuit of the second display region. The fifth connection segment 315 may be located in the second display region. For example, the fifth connection segment 315 and the fourth connection segment 314 may be connected and form a third corner a3 along the clockwise direction. The third corner a3 may be a clockwise included angle between the fourth connection segment 314 and the fifth connection segment 315. An angle of the third corner a3, for example, may be substantially the same as an angle of the second corner a2. For example, the angle of the third corner a3 may be about 135 degrees. However, the embodiment is not limited thereto.

FIG. 3D is a partial schematic diagram of a first connection line and a switching hole according to at least one embodiment of the present disclosure. In FIG. 3D, first connection segments 311 of a plurality of first-type first connection lines 31a are taken as an example for illustration. In some examples, as shown in FIG. 3D, the first display region may have a plurality of sub-pixel regions 40 arranged in an array, and each sub-pixel region 40 may be provided with a switching hole 41. For example, the sub-pixel region 40 may be a rectangular region. The plurality of sub-pixel regions 40 may be arranged in a plurality of columns along the first direction D1, and in a plurality of rows along a second direction D2. In sub-pixel regions of a same row, switching holes 41 within adjacent sub-pixel regions 40 may be misaligned in a row direction (i.e., the first direction D1). For example, a sub-pixel region of an i-th column may include a plurality of switching holes 41b arranged along the second direction D2, and a sub-pixel region of an (i+1)-th column may include a plurality of switching holes 41a arranged along the second direction D2. In sub-pixel regions of a same row, switching holes 41b and switching holes 41a within adjacent sub-pixel regions 40 are not aligned in the first direction D1 but are misaligned. For example, one sub-pixel region 40 may be equally divided into three setting regions (e.g., a first setting region 401, a second setting region 402, and a third setting region 403) with a same size and a same dimension along the second direction D2, a switching hole 41b may be located at a middle position of a third setting region 403 within a sub-pixel region 40 where the switching hole 41b is located, and a switching hole 41a may be located at a middle position of a first setting region 401 within a sub-pixel region 40 where the switching hole 41a is located.

In the example, as shown in FIGS. 3B to 3D, switching holes 41a and 41b of sub-pixel regions of different columns may be arranged at intervals substantially along the third direction D3, and the switching holes 41a and 41b of sub-pixel regions of different columns may also be arranged at intervals substantially along the fourth direction D4. In other words, a plurality of switching holes 41 within the first display region are arranged regularly in the third direction D3 and the fourth direction D4. For example, a plurality of switching holes 41 arranged along the fourth direction D4 may be referred to as a first group of switching holes 51, trace space exists between adjacent first group of switching holes 51, and first connection segments 311 (including, for example, eight first connection segments 311) of a group of first-type first connection lines 31a may be arranged between adjacent first group of switching holes 51, thereby achieving that the first connection segments 311 extend along the fourth direction D4. For example, first connection segments 311 of a group of first-type first connection lines 31a connected with one first group of switching holes 51 may all be located on a same side of the first group of switching holes 51. A plurality of switching holes 41 arranged along the third direction D3 may be referred to as a second group of switching holes 52 (as shown in FIG. 3C), trace space exists between adjacent second group of switching holes 52, and second connection segments 312 (including, for example, eight second connection segments 312) of a group of first-type first connection lines 31a may be arranged between adjacent second group of switching holes 52, so that it is achieved that the second connection segments 312 may extend along the third direction D3. A plurality of switching holes 41a arranged along the first direction D1 may be referred to as a first row of switching holes, a plurality of switching holes 41b arranged along the first direction D1 may be referred to as a second row of switching holes, and the first row of switching holes and the second row of switching holes may be arranged at intervals along the second direction D2. Third connection segments 313 of a plurality of first-type first connection lines 31a may be arranged within trace space between a first row of switching holes and an adjacent second row of switching holes, so that it is achieved that the third connection segments 313 may extend to the second display region along the first direction D1.

In some examples, as shown in FIGS. 3A to 3D, within the first sub-region, a plurality of first groups of switching holes 51 are arranged along the first direction D1. In each first group of switching holes 51, a plurality of switching holes (e.g., eight switching holes) close to the center of the first display region are electrically connected with a first connection segment 311 of a first-type first connection line 31a, and a plurality of switching holes (e.g., eight switching holes) close to the edge of the first display region are electrically connected with a fourth connection segment 314 of a second-type first connection line 31b. In the first direction D1 from the center to the edge of the first display region, a quantity of first-type first connection lines 31a connected with each first group of switching holes 51 may have a decreasing trend, for example, be gradually decreasing. A quantity of second-type first connection lines 31b connected with each first group of switching holes 51 may have a decreasing trend, for example, be gradually decreasing. As shown in FIGS. 3B and 3C, a second group of switching holes 52, which are closest to the center of the first display region, electrically connected with a second-type first connection line 31b may be adjacent to a first-type first connection line 31a in the fourth direction D4.

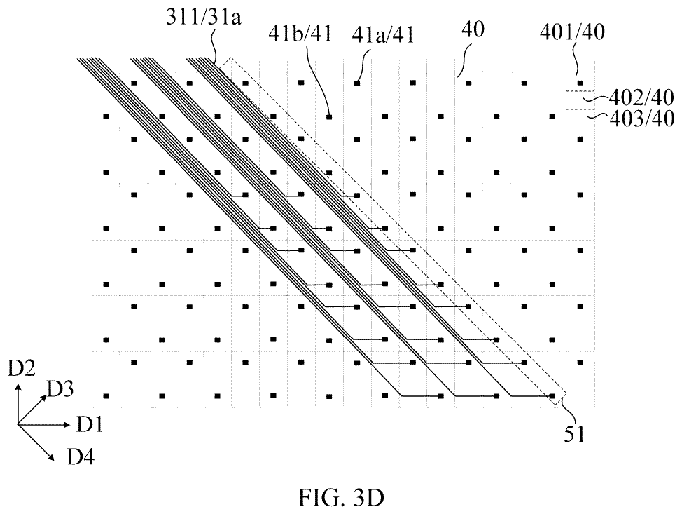

FIGS. 4A and 4B are partial trace diagrams of a second connection layer of a first display region according to at least one embodiment of the present disclosure. FIG. 4A is a schematic diagram of second connection lines within a first sub-region and a second sub-region. FIG. 4B is a schematic diagram of a second connection line within the first sub-region.

In some examples, as shown in FIGS. 4A and 4B, a plurality of second connection lines 32 of a second connection layer of the first sub-region may include a plurality of first-type second connection lines 32a and a plurality of second-type second connection lines 32b. A first light emitting element electrically connected with a plurality of first-type second connection lines 32a may be located on a side of a first light emitting element electrically connected with a plurality of second-type second connection lines 32b close to the center of the first display region.

In some examples, as shown in FIGS. 4A and 4B, a first-type second connection line 32a of the first sub-region may include a sixth connection segment 321, a seventh connection segment 322, and an eighth connection segment 323 connected in sequence. The sixth connection segment 321 at least extends along the fourth direction D4. For example, the sixth connection segment 321 may include a third main body 3211 extending along the fourth direction D4 and a third extension portion 3212 extending along the first direction D1, and the third extension portion 3212 of the sixth connection segment 321 may be electrically connected with an anode of a first light emitting element. The seventh connection segment 322 may extend along the third direction D3. The eighth connection segment 323 may extend from the first display region to the second display region along the first direction D1. The sixth connection segment 321 and the seventh connection segment 322 may be located in the first display region. The sixth connection segment 321 and the seventh connection segment 322 of the first-type second connection line 32a may be located on a side of a second-type second connection line 32b close to the center of the first display region. A trace form of the first-type second connection line 32a is similar to a trace form of a first-type first connection line 31a, which will not be repeated here.

In some examples, as shown in FIGS. 4A and 4B, a second-type second connection line 32b of the first sub-region may include a ninth connection segment 324 and a tenth connection segment (not shown) connected in sequence. The ninth connection segment 324 may be electrically connected with a first light emitting element in the first display region and extend to the second display region along the fourth direction. For example, the ninth connection segment 324 may include a fourth main body 3241 extending along the fourth direction D4 and a fourth extension portion 3242 extending along the first direction D1, and the fourth extension portion 3242 of the ninth connection segment 324 may be electrically connected with an anode of the first light emitting element. The tenth connection segment may at least extend along the first direction D1. A trace form of the second-type second connection line 32b is similar to a trace form of a second-type first connection line 31b, which will not be repeated here.

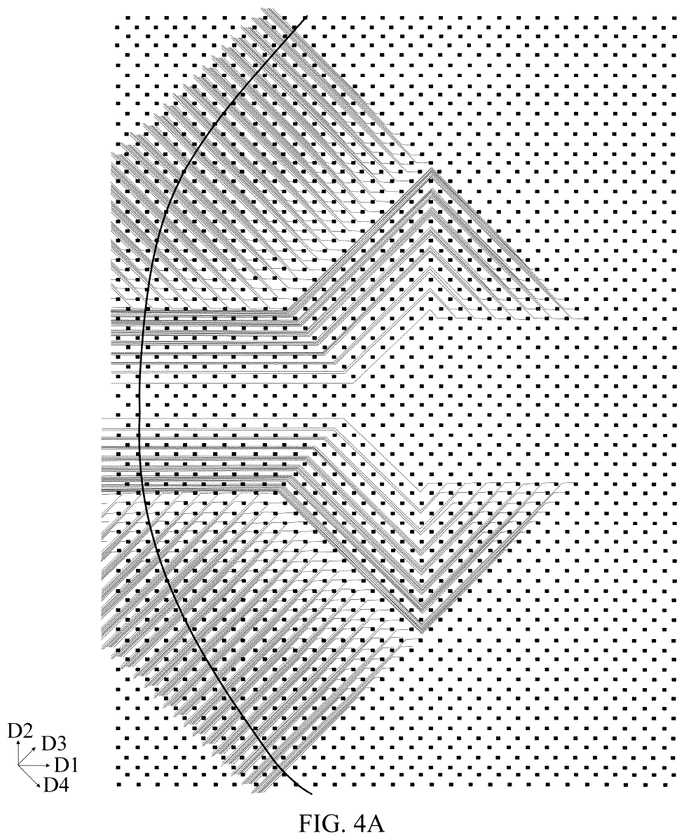

FIGS. 5A and 5B are partial trace diagrams of a third connection layer of a first display region according to at least one embodiment of the present disclosure. FIG. 5A is a schematic diagram of third connection lines within a first sub-region and a second sub-region. FIG. 5B is a schematic diagram of a third connection line within the first sub-region.

In some examples, as shown in FIGS. 5A and 5B, the third connection layer may include a plurality of third connection lines 33. A third connection line 33 may include an eleventh connection segment 331 and a twelfth connection segment (not shown) connected in sequence. The eleventh connection segment 331 may be electrically connected with a first light emitting element in the first display region and extend to the second display region along the fourth direction D4. For example, the eleventh connection segment 331 may include a fifth main body 3311 extending along the fourth direction D4 and a fifth extension portion 3312 extending along the first direction D1, and the fifth extension portion 3312 of the eleventh connection segment 331 may be electrically connected with an anode of the first light emitting element. The twelfth connection segment 315 may at least extend along the first direction D1 and is electrically connected with a first pixel circuit of the second display region. A trace form of the third connection line 33 is similar to a trace form of a second-type first connection line 31b, which will not be repeated here.

In some examples, as shown in FIGS. 3A to 5B, in a direction from the center to the edge of the first display region, a plurality of switching holes 41 within one first group of switching holes 51 may be electrically connected with first connection segments 311 of a plurality of first-type first connection lines 31a, sixth connection segments 321 of a plurality of first-type second connection lines 32a, a plurality of third connection lines 33, a plurality of second-type second connection lines 32b, and fourth connection segments 314 of a plurality of second-type first connection lines 31b in sequence. For example, a plurality of switching holes 41, in a direction from the center to the edge of the first display region, in a first group of switching hole 51 closest to the third centerline O3 within the first sub-region, may be electrically connected with first connection segments 311 of eight first-type first connection lines 31a, sixth connection segments 321 of eight first-type second connection lines 32a, eight third connection lines 33, eight second-type second connection lines 32b, and eight second-type first connection lines 31b in sequence. Among them, a first connection segment 311 of a first-type first connection line 31a turns to connect a second connection segment 312 before reaching a second-type first connection line 31b. That is, a first corner a1 is located on a side of the second-type first connection line 31b close to the center of the first display region. A sixth connection segment 321 of a first-type second connection line 32a turns to connect a seventh connection segment 322 before reaching a second-type second connection line 32b. That is, a third corner a3 is located on a side of the second-type second connection line 32b close to the center of the first display region. In this way, a first-type first connection line 31a and a second-type first connection line 31b do not interfere with each other, and a first-type second connection line 32a and a second-type second connection line 32b do not interfere with each other.

In the example, within the first display region, a mode of a turning trace is adopted for both a first-type first connection line 31a and a first-type second connection line 32a, which extend from the first display region to the second display region by means of a mode of a transverse trace, so that trace space within the first display region may be fully utilized, which facilitates increasing a size of the first display region. A combination mode of oblique and transverse traces is adopted for all of a second-type first connection line 31b, a second-type second connection line 32b, and a third connection line 33 to achieve an electrical connection between a first light emitting element and a first pixel circuit, which is beneficial to reasonable arrangement of traces. In some examples, a quantity of connection layers is related to the size of the first display region. The larger the quantity of connection layers, which is beneficial to increase the size of the first display region. In the example, three connection layers are used, which is not only beneficial to increase the size of the first display region, but also avoids increasing complexity of a preparation process and takes into account a production efficiency.

According to the display substrate provided by the embodiment, by arranging switching holes within adjacent sub-pixel regions in the first direction in a staggered manner in the first direction, arrangement space may be provided for oblique traces of connection lines (for example, traces along the third direction D3 and the fourth direction D4), so that trace setting space may be increased, and a lower connection layer may not be constrained by an upper connection line, and a quantity of the connection lines may be increased. For connection lines of the display substrate of the example, a combination mode of a turning trace and a transverse trace, and a combination mode of an oblique trace and a transverse trace are adopted, so that the size of the first display region may be increased. For example, a display substrate with a resolution of 429 Pixel Per Inch (PPI) (for example, a size of a sub-pixel region may be about 29.6 microns (μm)×59.2 μm) is taken as an example, an electrical connection of 48 columns of first light emitting elements may be achieved at most by using a connection line mode of the example, and a maximum diameter of a corresponding first display region may be about 4.0186 millimeters (mm). However, a transverse trace mode along the first direction is adopted for connection lines, which can only achieve an electrical connection of 42 columns of first light emitting elements at most, and a maximum diameter of a corresponding first display region is only about 2.4864 mm. The maximum diameter of the first display region in the example may be increased by about 61.6% compared with a case that only a transverse trace mode is adopted for connection lines. The size of the first display region in the example is increased, which may be beneficial to satisfying a better photographing experience, achieving a better infrared recognition effect and the like.

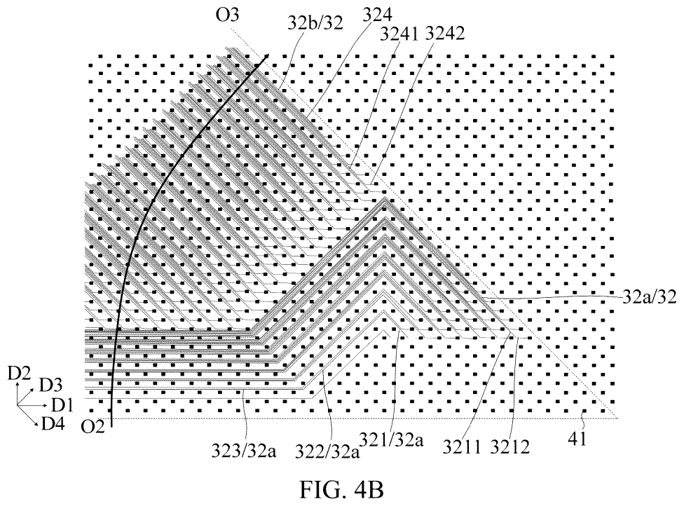

FIG. 6 is a schematic diagram of a resistance change of a connection line with which a row of first light emitting elements of a first display region within a display substrate are electrically connected. In FIG. 6, an ordinate denotes a resistance and an abscissa denotes a number of a first light emitting element along the first direction from the edge to the center of the first display region. As shown in FIG. 6, for a row of first light emitting elements, a resistance of a connection line electrically connected with a first light emitting element close to the edge of the first display region is quite different from a resistance of a connection line electrically connected with a first light emitting element close to the center of the first display region, in this way, uneven lengths of connection lines is easily to lead to a situation of striped display Mura. Moreover, at a junction of an oblique trace and a transverse trace, it is easy to have a sudden change in length, which leads to a sudden change in resistance. For the display substrate in the example, close to the center of the first display region, a connection line pulling mode of combining a turning trace and a transverse trace is adopted, and close to the edge of the first display region, a connection line pulling mode of combining an oblique trace and a transverse trace is adopted, which may effectively improve the situation of striped display Mura caused by uneven lengths of connection lines to a certain extent.

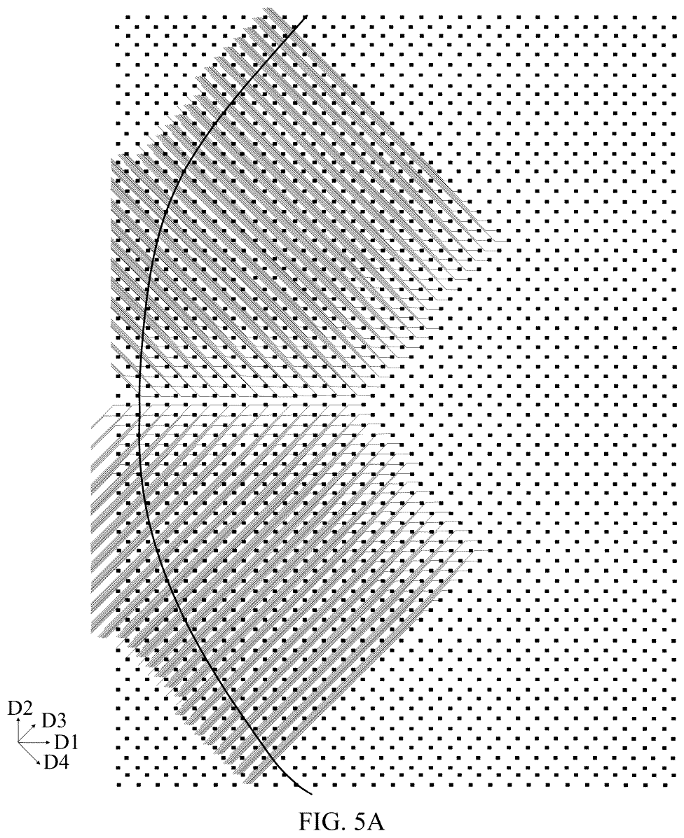

FIG. 7A is another partial schematic diagram of a first connection line and a switching hole according to at least one embodiment of the present disclosure. In FIG. 7A, a plurality of first connection lines 31 are taken as an example for illustration. In some examples, as shown in FIG. 7A, the first display region may have a plurality of sub-pixel regions 40 arranged in an array, and each sub-pixel region 40 may be provided with a switching hole 41. For example, the sub-pixel region 40 may be a rectangular region. The plurality of sub-pixel regions 40 may be arranged in a plurality of columns along the first direction D1, and in a plurality of rows along the second direction D2. In sub-pixel regions of a same row, switching holes 41 within adjacent sub-pixel regions 40 are misaligned in a row direction (i.e., the first direction D1). For example, in sub-pixel regions of a same row, switching holes 41e and 41c within adjacent sub-pixel regions 40 are not aligned in the first direction D1, the switching hole 41e may be located in an upper left corner of a sub-pixel region 40 where the switching hole 41e is located, and the switching hole 41c may be located in a lower left corner of a sub-pixel region 40 where the switching hole 41c is located. A column of sub-pixel regions may include a plurality of first sub-pixel region units arranged in sequence along the second direction D2, each first sub-pixel region unit may include two sub-pixel regions adjacent to each other along the second direction D2, and two switching holes 41 within a first sub-pixel region unit are adjacent to each other. For example, two switching holes 41d and 41e within a first sub-pixel region unit are adjacent in the second direction D2. The switching hole 41d may be located at a lower left corner of a sub-pixel region where the switching hole 41d is located, and the switching hole 41e may be located at an upper left corner of a sub-pixel region where the switching hole 41e is located.

In some examples, as shown in FIG. 7A, two switching holes (e.g., switching holes 41d and 41e) within each first sub-pixel region unit may serve as one first switching hole unit 530, and a plurality of first switching hole units 530 may be arranged at intervals along the first direction D1 and arranged at intervals along the second direction D2. A plurality of first switching hole units 530 may be arranged in sequence along the third direction D3 and may also be arranged in sequence along the fourth direction D4. A plurality of first switching hole units 530 arranged along the fourth direction D4 may serve as a group of first switching hole units 53, and trace space exists between adjacent groups of first switching hole units 53. For example, first connection segments of a group of first connection lines 31 (including, for example, eight first connection lines 31) connected with a group of first switching hole units 53 may be arranged between the group of first switching hole units and an adjacent group of first switching hole units. An arrangement mode of other connection lines may be referred to description of the foregoing embodiments, which will not be repeated here.

FIG. 7B is another partial schematic diagram of a first connection line and a switching hole according to at least one embodiment of the present disclosure. In FIG. 7B, a plurality of first connection lines 31 are taken as an example for illustration. In some examples, as shown in FIG. 7B, the first display region may have a plurality of sub-pixel regions 40 arranged in an array, and each sub-pixel region 40 may be provided with a switching hole 41. For example, the sub-pixel region 40 may be a rectangular region. The plurality of sub-pixel regions 40 may be arranged in a plurality of columns along the first direction D1, and in a plurality of rows along the second direction D2. In the example, four sub-pixel regions 40 arranged in a 2×2 array serve as one second sub-pixel region unit and each second sub-pixel region unit may include four switching holes 41 such as switching holes 41f, 41g, 41i, and 41h. The four switching holes 41 within the second sub-pixel region unit may serve as a second switching hole unit 540, and the four switching holes 41 within the second switching hole unit 540 may be centrally arranged with a center of the second sub-pixel region unit as a center. For example, the switching hole 41f may be located at a lower right corner of a sub-pixel region where the switching hole 41f is located, the switching hole 41g may be located at a lower left corner of a sub-pixel region where the switching hole 41g is located, the switching hole 41h may be located at an upper right corner of a sub-pixel region where the switching hole 41h is located, and the switching hole 41i may be located at an upper left corner of a sub-pixel region where the switching hole 41i is located.

In some examples, as shown in FIG. 7B, a plurality of second switching hole units 540 may be sequentially arranged along the first direction D1 and sequentially arranged along the second direction D2. A plurality of second switching hole units 540 may be sequentially arranged along the third direction D3 and may also be sequentially arranged along the fourth direction D4. The plurality of second switching hole units 540 arranged along the fourth direction D4 may serve as a group of second switching hole units 54, and trace space exists between adjacent groups of second switching hole units 54. For example, first connection segments of a group of first connection lines 31 (including, for example, eight first connection lines 31) connected with a group of second switching hole units 54 may be arranged between the group of second switching hole units and an adjacent group of second switching hole units. An arrangement mode of other connection lines may be referred to description of the foregoing embodiments, which will not be repeated here.

FIG. 7C is another partial schematic diagram of a first connection line and a switching hole according to at least one embodiment of the present disclosure. In FIG. 7C, a plurality of first connection lines 31 are taken as an example for illustration. In some examples, as shown in FIG. 7C, the first display region may have a plurality of sub-pixel regions 40 arranged in an array, and each sub-pixel region 40 may be provided with a switching hole 41. For example, the sub-pixel region 40 may be a rectangular region. The plurality of sub-pixel regions 40 may be arranged in a plurality of columns along the first direction D1, and in a plurality of rows along the second direction D2. In sub-pixel regions of a same row, switching holes 41 within adjacent sub-pixel regions 40 are misaligned in a row direction (i.e., the first direction D1). For example, in sub-pixel regions of a same row, a switching hole 41j within a sub-pixel region 40 of an i-th column may be located in an upper right corner of a sub-pixel regions 40 where the switching hole 41j is located, a switching hole 41k within a sub-pixel region 40 of an (i+1)-th column may be located in an upper left corner of a sub-pixel regions 40 where the switching hole 41k is located, a switching hole 41l within a sub-pixel region 40 of an (i+2)-th column may be located in a lower right corner of a sub-pixel regions 40 where the switching hole 41l is located, and a switching hole 41m within a sub-pixel region 40 of an (i+3)-th column may be located in a lower left corner of a sub-pixel regions 40 where the switching hole 41m is located.

In some examples, as shown in FIG. 7C, four sub-pixel regions arranged sequentially along the first direction D1 may serve as one third sub-pixel region unit, four switching holes (e.g., switching holes 41j, 41k, 41l, and 41m) in each third sub-pixel region unit may serve as one third switching hole unit 550, and a plurality of third switching hole units 550 may be arranged at intervals along the first direction D1 and arranged at intervals along the second direction D2. The plurality of third switching hole units 550 may be sequentially arranged along the third direction D3 and may also be sequentially arranged along the fourth direction D4. A plurality of third switching hole units 550 arranged along the fourth direction D4 may serve as a group of third switching hole units 55, and trace space exists between adjacent groups of third switching hole units 55. For example, first connection segments of a group of first connection lines 31 (including, for example, six first connection lines 31) connected with a group of third switching hole units 55 may be arranged between the group of third switching hole units and an adjacent group of third switching hole units. An arrangement mode of other connection lines may be referred to description of the foregoing embodiments, which will not be repeated here.

FIG. 7D is another partial schematic diagram of a first connection line and a switching hole according to at least one embodiment of the present disclosure. In FIG. 7D, a plurality of first connection lines 31 are taken as an example for illustration. In some examples, as shown in FIG. 7D, the first display region may have a plurality of sub-pixel regions 40 arranged in an array, and each sub-pixel region 40 may be provided with a switching hole 41. For example, the sub-pixel region 40 may be a rectangular region. The plurality of sub-pixel regions 40 may be arranged in a plurality of columns along the first direction D1, and in a plurality of rows along the second direction D2. In sub-pixel regions of a same row, switching holes 41 within adjacent sub-pixel regions 40 are misaligned in a row direction (i.e., the first direction D1). For example, in sub-pixel regions of a same row, a switching hole 41n within a sub-pixel region 40 of an i-th column may be located in an upper left corner of a sub-pixel region 40 where the switching hole 41n is located and a switching hole 410 within a sub-pixel region 40 of an (i+1)-th column may be located in a middle region of a left half of a sub-pixel region 40 where the switching hole 410 is located.

In some examples, as shown in FIG. 7D, two sub-pixel regions arranged sequentially along the first direction D1 may serve as one fourth sub-pixel region unit, two switching holes (e.g., switching holes 41n and 410) in each fourth sub-pixel region unit may serve as one fourth switching hole unit 560, and a plurality of fourth switching hole units 560 may be arranged at intervals along the first direction D1 and arranged at intervals along the second direction D2. A plurality of fourth switching hole units 560 may be sequentially arranged along the third direction D3 and may also be sequentially arranged along the fourth direction D4. The plurality of fourth switching hole units 560 arranged along the fourth direction D4 may serve as a group of fourth switching hole units 56, and trace space exists between adjacent groups of fourth switching hole units 56. For example, first connection segments of a group of first connection lines 31 (including, for example, six first connection lines 31) connected with a group of fourth switching hole units 56 may be arranged between the group of fourth switching hole units and an adjacent group of fourth switching hole units. An arrangement mode of other connection lines may be referred to description of the foregoing embodiments, which will not be repeated here.

In other examples, setting positions of switching holes within adjacent sub-pixel regions may be adaptively adjusted as long as arrangement of traces extending along the fourth direction may be achieved.

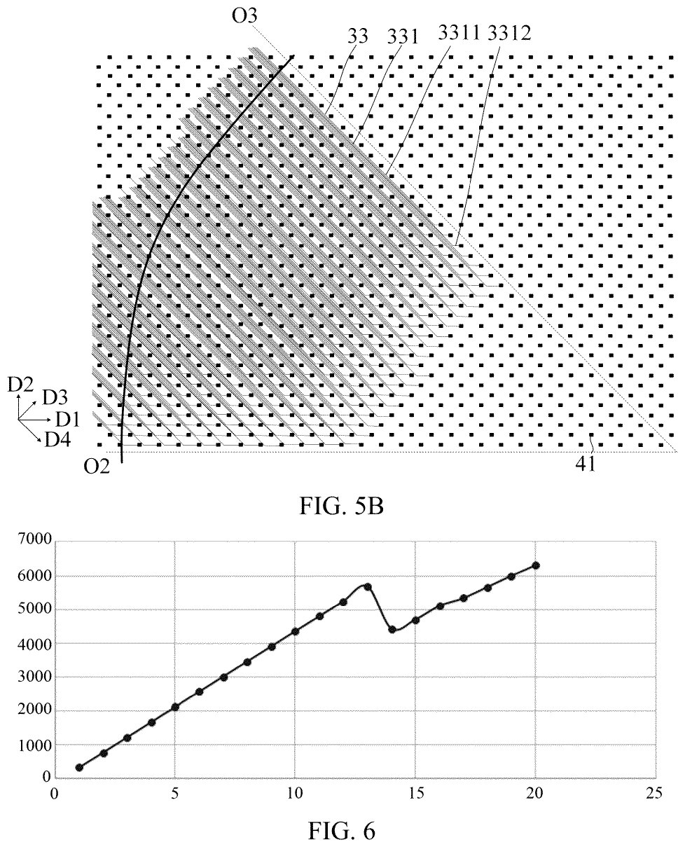

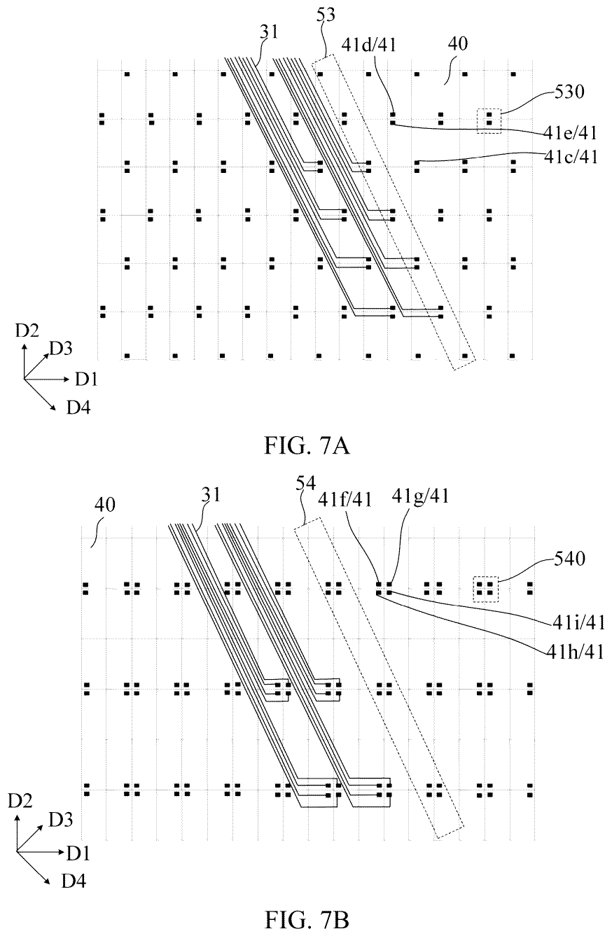

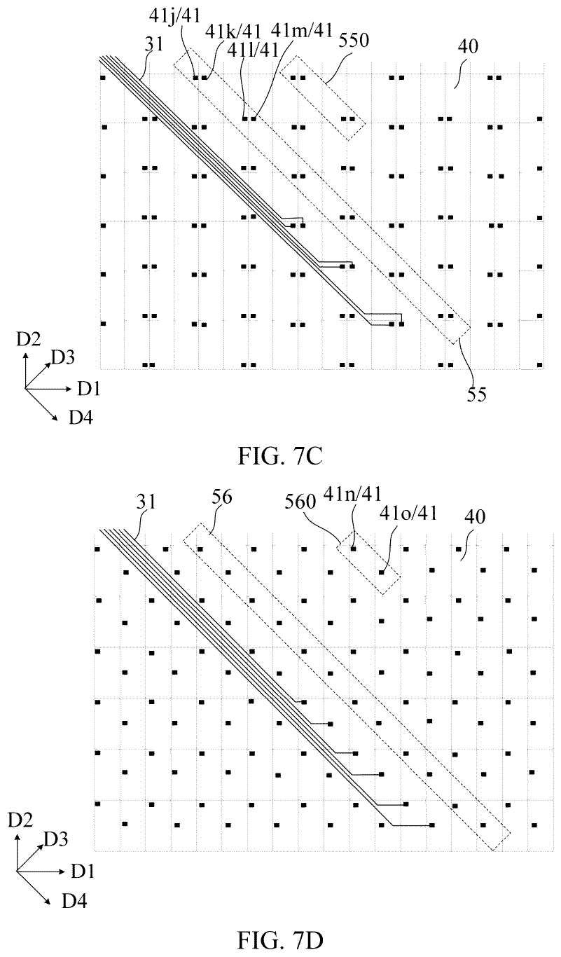

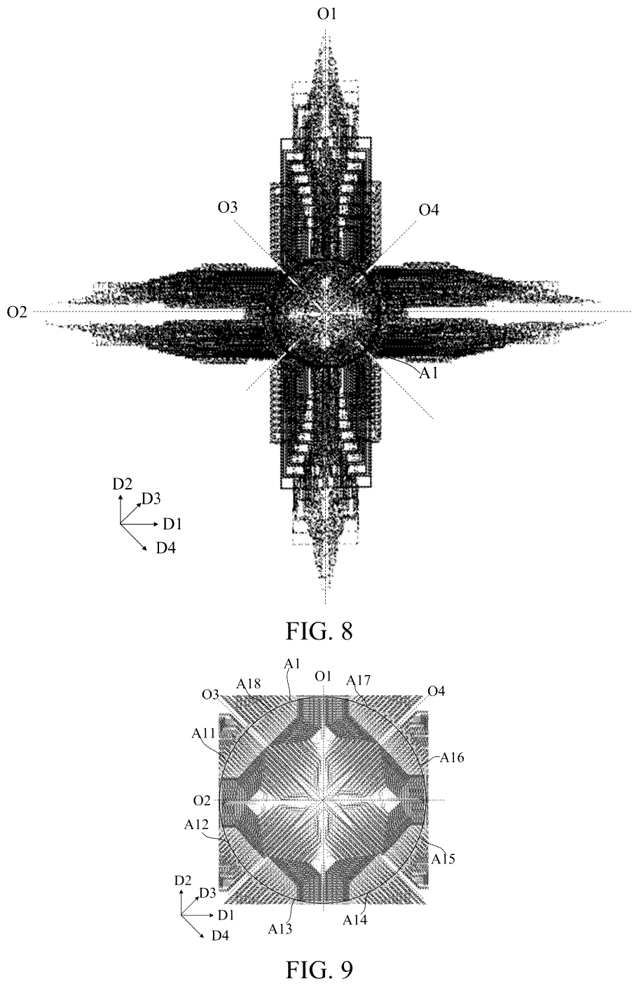

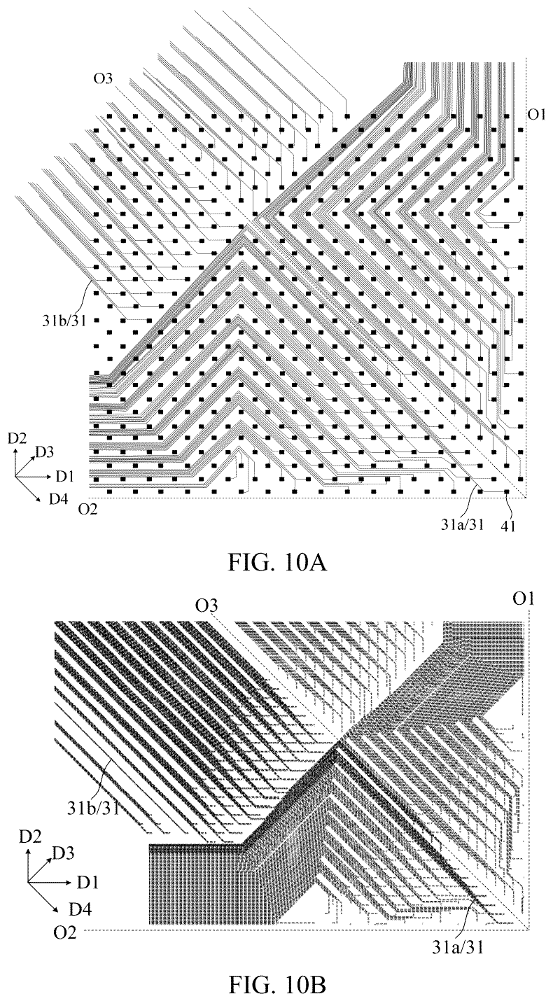

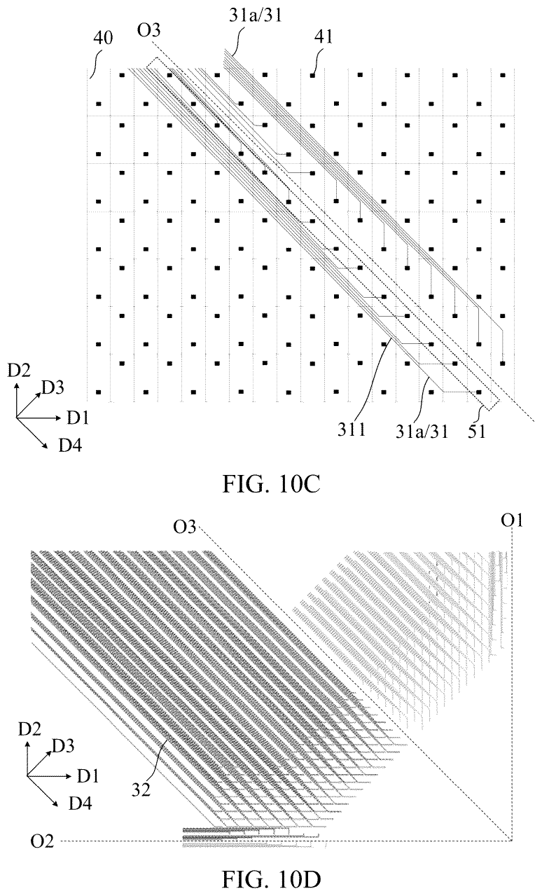

FIG. 8 is another schematic diagram of a connection line of a display substrate according to at least one embodiment of the present disclosure. FIG. 9 is another schematic diagram of a connection line of a first display region according to at least one embodiment of the present disclosure. FIG. 10A is a partial schematic diagram of a first connection line and a switching hole of a first display region according to at least one embodiment of the present disclosure. FIG. 10B is a partial schematic diagram of a first connection line of a first display region according to at least one embodiment of the present disclosure. FIG. 10C is a partial schematic diagram of a first connection line and a switching hole according to at least one embodiment of the present disclosure. FIG. 10D is a partial schematic diagram of a second connection line of a first display region according to at least one embodiment of the present disclosure. FIGS. 10A, 10B, 10C, and 10D are partial trace diagrams of a first sub-region and an eighth sub-region of the first display region.

In some examples, as shown in FIGS. 8 and 9, a first display region A1 of the example may be circular, for example, may be divided into a first sub-region A11 to an eighth sub-region A18 by a first centerline O1, a second centerline O2, a third centerline O3, and a fourth centerline O4.

In some examples, the display substrate may be provided with a first connection layer and a second connection layer between a circuit structure layer and a light emitting structure layer. A first planarization layer is disposed between the first connection layer and the second connection layer, and a second planarization layer is disposed between the second connection layer and the light emitting structure layer. Compared with a previous embodiment, a third connection layer and a third planarization layer are omitted in the embodiment.

In some examples, a switching hole corresponding to an anode of a first light emitting element may include: a second switching hole opened in the second planarization layer, wherein an anode of a second light emitting element may be electrically connected with a second connection line located in the second connection layer through the second switching hole opened in the second planarization layer. For another example, the switching hole corresponding to the anode of the first light emitting element may include a second switching hole opened in the second planarization layer and a first switching hole opened in the first planarization layer, wherein the anode of the second light emitting element may be electrically connected with a second connection electrode located in the second connection layer through the second switching hole, the second connection electrode is electrically connected with a first connection electrode located in the first connection layer through the first switching hole, the first connection electrode and the first connection line may be of an integral structure, and the first connection electrode may be electrically connected with a first pixel circuit of a second display region through the first connection line.

A connection line of a first sub-region is taken as an example for description below.

In some examples, as shown in FIGS. 10A and 10B, a first connection layer of the first sub-region may include a plurality of first connection lines 31, and the plurality of first connection lines 31 include a plurality of first-type first connection lines 31a and a plurality of second-type first connection lines 31b. As shown in FIG. 10C, a plurality of first-type first connection lines 31a connected with a first group of switching holes 51 (including a plurality of switching holes 41 arranged along the fourth direction D4) close to the third centerline O3 within the first sub-region may be distributed on opposite sides of the first group of switching holes 51 along the third direction D3. For example, eight first-type first connection lines 31a close to the center of the first display region may be arranged on a side of the first group of switching holes 51 away from the third centerline O3, and four first-type first connection lines 31a may be arranged on a side of the first group of switching holes 51 close to the third centerline O3. Similarly, there is similar arrangement within the eighth sub-region. In the example, a plurality of first-type first connection lines connected with a first group of connection holes 51 may be located on opposite sides of the first group of connection holes 51, which is beneficial to increase trace space, and a quantity of connection layers may be reduced by increasing a quantity of connection lines of a single connection layer. Moreover, a problem of resistance uniformity of the connection lines may be improved, for example, a jump resistance between resistance jump points shown in FIG. 6 may be reduced.

In some examples, a manner of being arranged on both sides of a first group of connection holes 51 may be only adopted for first connection segments 311 of a plurality of first-type first connection lines 31a connected with the first group of connection holes 51 close to the third centerline O3, and first connection segments 311 of a plurality of first-type first connection lines 31a connected with a remaining first group of connection holes may be arranged on one side of a corresponding first group of connection holes. In other examples, for a plurality of first connection segments connected with each first group of switching holes, a manner of being arranged on both sides of the first group of connection holes 51 may all be adopted, as long as a number of traces between adjacent first groups of switching holes is approximately the same. The embodiment is not limited thereto, and a trace position of a first connection line may be reasonably arranged according to a quantity of first light emitting elements within the first display region.

In some examples, as shown in FIG. 10D, the second connection layer of the first sub-region may include a plurality of second connection lines 32. For example, at least one second connection line 32 may extend along the fourth direction D4. A trace form of the second connection line 32 may be referred to a trace form of a third connection line according to a previous embodiment, which will not be repeated here.

For the rest of the structure of the display substrate according to the embodiment, reference may be made to description of the previous embodiment, and repetition will not be made here.

An embodiment of the present disclosure also provides a display apparatus, which includes the aforementioned display substrate.

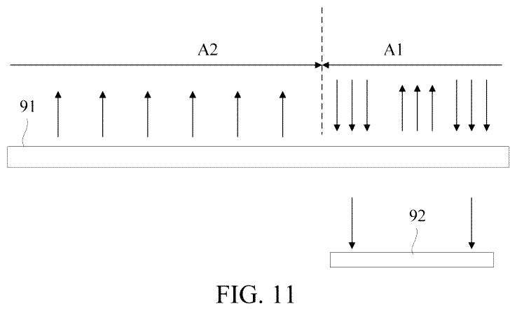

FIG. 11 is a schematic diagram of a display apparatus according to at least one embodiment of the present disclosure. As shown in FIG. 11, an embodiment provides a display apparatus, which includes a display substrate 91 and a photosensitive sensor 92 located on a light exit side of a display structure layer away from the display substrate 91. An orthographic projection of the photosensitive sensor 92 on the display substrate 91 is overlapped with the first display region A1.

In some examples, the display substrate 91 may be a flexible OLED display substrate, a QLED display substrate, a Micro-LED display substrate, or a Mini-LED display substrate. The display apparatus may be any product or component with a display function such as an OLED display, a cell phone, a tablet computer, a television, a display, a laptop computer, a digital photo frame, and a navigator, which is not limited in the embodiments of the present disclosure.

The drawings of the present disclosure only involve structures involved in the present disclosure, and other structures may be referred to conventional designs. The embodiments of the present disclosure and features in the embodiments may be combined with each other to obtain new embodiments if there is no conflict. Those of ordinary skills in the art should understand that modifications or equivalent replacements may be made to the technical solutions of the present disclosure without departing from the spirit and scope of the technical solutions of the present disclosure, and should be included in the scope of the claims of the present disclosure.

1. A display substrate, comprising:
a base substrate comprising a first region and a second region located on at least one side of the first region;
a plurality of first pixel circuits located in the second region;
a plurality of first light emitting elements located in the first display region; and
a plurality of connection lines;
wherein at least one first pixel circuit among the plurality of first pixel circuits is electrically connected with at least one first light emitting element among the plurality of first light emitting elements through at least one connection line among the plurality of connection lines;
the plurality of connection lines at least comprise a plurality of first connection lines located in a first connection layer, wherein the plurality of first connection lines comprise at least one first-type first connection line; the at least one first-type first connection line comprises a first connection segment, a second connection segment, and a third connection segment connected in sequence, wherein the first connection segment is connected with the at least one first light emitting element, the third connection segment extends from the first region to the second region and is electrically connected with a first pixel circuit in the second region; extension directions of the first connection segment, the second connection segment, and the third connection segment are different from each other.

2. The display substrate according to claim 1, wherein the first connection segment and the second connection segment of the at least one first-type first connection line are connected and form a first corner along a clockwise direction, the second connection segment and the third connection segment are connected and form a second corner along a counter-clockwise direction, and the first corner is smaller than the second corner.

3. The display substrate according to claim 1, wherein extension directions of the first connection segment and the second connection segment of the at least one first-type first connection line are perpendicular; the plurality of first pixel circuits are arranged in an array, and an extension direction of at least part of the third connection segment is parallel to a row direction of the plurality of first pixel circuits.

4. The display substrate according to claim 1, wherein the plurality of first connection lines further comprise at least one second-type first connection line;
the first connection segment and the second connection segment of the at least one first-type first connection line are located on a side of the at least one second-type first connection line close to a center of the first region.

5. The display substrate according to claim 4, wherein the at least one second-type first connection line comprises a fourth connection segment and a fifth connection segment connected in sequence, wherein the fourth connection segment is electrically connected with at least one first light emitting element and extends from the first region to the second region, and the fifth connection segment is electrically connected with a first pixel circuit in the second region; an extension direction of the fourth connection segment is different from an extension direction of the fifth connection segment, and the extension direction of the fifth connection segment is approximately the same as an extension direction of the third connection segment of the first-type first connection line.

6. The display substrate according to claim 4, wherein the plurality of connection lines further comprise a plurality of second connection lines located in a second connection layer, and the second connection layer is located on a side of the first connection layer away from the base substrate;
a first light emitting element electrically connected with at least one second connection line among the plurality of second connection lines is located between a first light emitting element electrically connected with the at least one first-type first connection line and a first light emitting element electrically connected with the at least one second-type first connection line.

7. The display substrate according to claim 6, wherein the plurality of second connection lines comprise at least one first-type second connection line and at least one second-type second connection line;
the at least one first-type second connection line comprises a sixth connection segment, a seventh connection segment, and an eighth connection segment connected in sequence, wherein the sixth connection segment is connected electrically with the at least one first light emitting element, the eighth connection segment extends from the first region to the second region and is electrically connected with a first pixel circuit in the second region; extension directions of the sixth connection segment, the seventh connection segment, and the eighth connection segment are different from each other;
the sixth connection segment and the seventh connection segment of the at least one first-type second connection line are located on a side of the at least one second-type second connection line close to the center of the first region.

8. The display substrate according to claim 7, wherein an extension direction of the sixth connection segment of the at least one first-type second connection line is substantially the same as an extension direction of the first connection segment of the at least one first-type first connection line, an extension direction of the seventh connection segment of the at least one first-type second connection line is substantially the same as an extension direction of the second connection segment of the at least one first-type first connection line, and an extension direction of the eighth connection segment of the at least one first-type second connection line is substantially the same as an extension direction of the third connection segment of the at least one first-type first connection line.

9. The display substrate according to claim 4, wherein the plurality of connection lines further comprise a plurality of third connection lines located in a third connection layer, and the third connection layer is located on a side of the second connection layer away from the base substrate;
a first light emitting element electrically connected with at least one third connection line among the plurality of third connection lines is located between a first light emitting element electrically connected with the at least one first-type second connection line and a first light emitting element electrically connected with the at least one second-type second connection line.

10. The display substrate according to claim 9, wherein in a direction from the center to an edge of the first region, a plurality of first light emitting elements arranged along an extension direction of the first connection segment are electrically connected with at least one first-type first connection line, at least one first-type second connection line, at least one third connection line, at least one second-type second connection line, and at least one second-type first connection line in sequence.

11. The display substrate according to claim 1, wherein the first region has a plurality of sub-pixel regions arranged in an array, each sub-pixel region is provided with a switching hole, and an anode of the first light emitting element is electrically connected with a corresponding connection line through the switching hole.

12. The display substrate according to claim 11, wherein in a row of sub-pixel regions, switching holes within adjacent sub-pixel regions are misaligned in a row direction.

13. The display substrate according to claim 12, wherein a column of sub-pixel regions comprises a plurality of first sub-pixel region units arranged in sequence, each first sub-pixel region unit comprises two adjacent sub-pixel regions, and two switching holes within each first sub-pixel region unit are close to a junction position of the two sub-pixel regions.

14. The display substrate according to claim 11, wherein four sub-pixel regions arranged in a 2×2 array are used as one second sub-pixel region unit, and four switching holes within each second sub-pixel region unit are centrally arranged with a center of the second sub-pixel region unit as a center.

15. The display substrate according to claim 11, wherein a plurality of switching holes arranged along an extension direction of the first connection segment are taken as a group of switching holes, and a plurality of first-type first connection lines electrically connected with the first light emitting element through the group of switching holes are located on one side of the group of switching holes.

16. The display substrate according to claim 11, wherein a plurality of switching holes arranged along an extension direction of the first connection segment are taken as a group of switching holes, and a plurality of first-type first connection lines electrically connected with the first light emitting element through the group of switching holes are located on two opposite sides of the group of switching holes.

17. The display substrate according to claim 1, wherein a material of the plurality of connection lines comprises a transparent conductive material.

18. The display substrate according to claim 1, further comprising: a plurality of second pixel circuits and a plurality of second light emitting elements located in the second region, wherein at least one second pixel circuit among the plurality of second pixel circuits is electrically connected with at least one second light emitting element among the plurality of second light emitting elements.

19. A display apparatus, comprising a display substrate according to claim 1.

20. The display substrate according to claim 2, wherein extension directions of the first connection segment and the second connection segment of the at least one first-type first connection line are perpendicular; the plurality of first pixel circuits are arranged in an array, and an extension direction of at least part of the third connection segment is parallel to a row direction of the plurality of first pixel circuits.
